(19) United States
(12) Patent Application Publication
(10) Pub. No.: US 2025/0378208 A1
(43) Pub. Date: Dec. 11, 2025

(54) METHODS AND APPARATUS TO EVALUATE THE SMOOTHNESS OF A SURFACE

(71) Applicant: The Boeing Company, Arlington, VA (US)

(72) Inventors: Craig Martin Farniok, Godfrey, IL (US); Christopher Liberio, Saint Charles, MO (US); David Lawrence Fritsche, Foristell, MO (US); MacKinzie Hart Washington, Florissant, MO (US)

(21) Appl. No.: 18/734,433

(22) Filed: Jun. 5, 2024

(51) Int. Cl. G06F 30/10

(52) U.S. Cl. CPC G06F 30/10

(57) ABSTRACT

Methods and apparatus to evaluate the smoothness of a surface are disclosed. An example apparatus comprises interface circuitry, machine-readable instructions, and at least one processor circuit to be programmed by the machine-readable instructions to access a computer-generated model of a surface of an object to be evaluated for smoothness, segment the surface into a plurality of regions, each of the regions adjacent to or overlapping at least another one of the regions, select one of the regions to be evaluated for smoothness, measure a plurality of coordinates on the surface of the object corresponding to respective locations within the selected region, determine a reference surface based on the measured coordinates, compare the coordinates to the reference surface, and determine a smoothness parameter of the selected region based on the comparisons.

### FIELD OF THE DISCLOSURE

This disclosure relates generally to measurement systems and, more particularly, to methods and apparatus to evaluate the smoothness of a surface.

### BACKGROUND

Smooth, uniform surfaces of various aircraft components can enhance the performance and efficiency of an associated aircraft. In some examples, paints, coatings and/or other example films can provide additional benefits to the aerodynamic performance of such surfaces. Example measurement systems can be configured to evaluate characteristics of surfaces of some example components (e.g., aircraft components, automotive components, etc.) and/or to determine whether coating, paint, surface films, etc., can be applied thereto or removed therefrom.

### BRIEF DESCRIPTION OF THE DRAWINGS

FIG. 1 is a block diagram of an example environment in which example surface evaluator circuitry operates to evaluate the smoothness of a computer-generated model of a surface an object.

FIGS. 2A-2D illustrate various operations in an example process of implementing the example surface evaluator circuitry of FIG. 1.

FIGS. 3A and 3B illustrate additional example operations of the example process of FIGS. 2A-2D.

FIGS. 4 and 5 are flowcharts representative of example machine readable instructions and/or example operations that may be executed, instantiated, and/or performed by example programmable circuitry to implement the surface evaluator circuitry of FIG. 1.

FIG. 6 is a block diagram of an example processing platform including programmable circuitry structured to execute, instantiate, and/or perform the example machine readable instructions and/or perform the example operations of FIGS. 4 and 5 to implement the surface evaluator circuitry of FIG. 1.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

Smooth, uniform surfaces of aircraft components can enhance the performance/efficiency of an associated aircraft. In some examples, coatings and/or other example surface treatments (e.g., paints, surface films, etc.) deposited on surfaces of aircraft components can provide additional benefits to aerodynamic performance. However, these coatings may affect (e.g., change, degrade, etc.) the smoothness of the surfaces. As such, after coating deposition, surfaces of aircraft components may be evaluated, assessed, tested, etc., by measurement systems to ensure conformance to smoothness requirements. While examples disclosed herein may be described with reference to aircraft components, surface conformance may be evaluated in the context of any industry (e.g., automotive, maritime, spacecraft, electronics, etc.) and/or any component.

Measurement systems designed to evaluate surface smoothness are typically limited to two dimensions. Curved and/or contoured surfaces may not be compatible with conventional measurement systems. In other words, conventional measurement systems fail to provide three-dimensional (3D) evaluation capabilities to assess the smoothness of contoured surfaces. Such conventional systems may include devices such as straight edge with a template gage, a feeler gage, etc., that provide measurements based on tactile feedback to a human operator. For example, a human operator may determine that a surface is smooth if he/she experiences little to no tactile feedback from a template gage after passing the template over the surface. As such, these measurement systems rely on the judgment/interpretation of an operator and, thus, are subjective in nature. Moreover, the results of these measurements are seldom, if at all, digitally preserved in a database or other data store for reference thereafter.

Examples disclosed herein provide localized surface evaluation analyses for different regions of a curved/contoured surface. Disclosed examples provide mathematical computations and numerical outputs to indicate the smoothness of each region of a curved/contoured surface. As such, examples disclosed herein reduce and/or eliminate subjective judgments of a human operator when evaluating a surface for smoothness. Further, examples disclosed herein evaluate each region of the surface individually for smoothness. Thus, disclosed examples can indicate which regions, areas, portions, etc., of an example surface are sufficiently smooth. To that end, disclosed examples can identify which regions of an example surface need to be redesigned, reevaluated, fixed, repaired, etc., instead of discarding the entire surface or the entire part. Disclosed examples can store and/or save results of these individual smoothness evaluations on a server, a workstation, etc. This allows examples disclosed herein access to historical data to better inform manufacturing decisions and design of other components/parts.

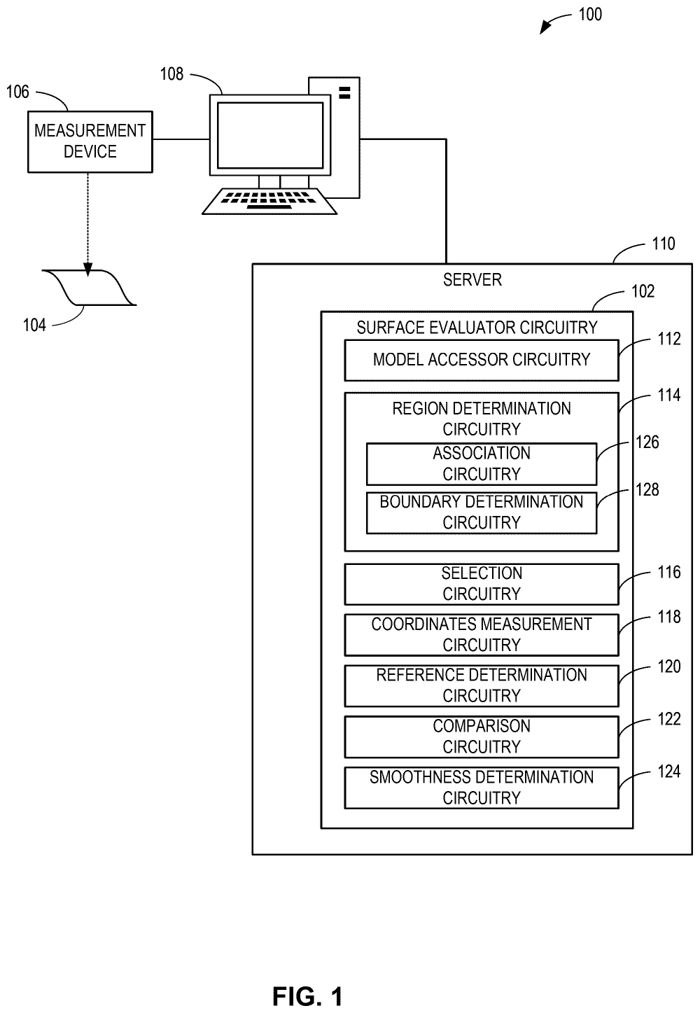

FIG. 1 is a block diagram of an example environment 100 in which example surface evaluator circuitry 102 operates to evaluate the smoothness of a computer-generated model of an example surface 104. In some examples, the surface 104 may be part of an object, a component, a device, etc. The example environment 100 includes the surface 104, an example measurement device 106, an example computer 108, and an example server 110.

In the example of FIG. 1, the computer 108 is conductively coupled to the measurement device 106 and the server 110. However, the computer 108 may be communicatively coupled to at least one of the measurement device 106 or the server 110 via a network. In some examples, the network is the Internet. However, the example network may be implemented using any suitable wired and/or wireless network(s) including, for example, one or more data buses, one or more local area networks (LANs), one or more wireless LANs (WLANs), one or more cellular networks, one or more coaxial cable networks, one or more satellite networks, one or more private networks, one or more public networks, etc.

The example computer 108 may be a laptop computer, a desktop computer, a workstation, etc. In some examples, the environment 100 may be a testing environment or a laboratory environment in which the computer 108 evaluates (e.g., tests, measures, examines, etc.) parts, devices, components, etc., via the measurement device 106. In some examples, the measurement device 106 is an optical comparator, a roughness tester, laser, or any other device or sensor configured to evaluate the surface 104. For example, the measurement device 106 can evaluate/capture the surface 104 and, in turn, transmits dimensional measurement data associated with the surface 104 to the computer 108 (e.g., via a network). The computer 108 can evaluate the dimensional measurement data and, in turn, extract surface measurements (e.g., surface distances, peak-to-valley measurements, etc.) from the dimensional measurement data. In some examples, the measurement device 106 transmits a computer-generated (e.g., 3D) model of the surface 104 to the computer 108. As used herein, the “computer-generated model of the surface 104” refers to a representation (e.g., graphics, data, numbers, etc.) and/or definition of the surface 104 generated by the computer 108. The example computer 108 includes a user interface to display and/or otherwise make the computer-generated model of the surface 104 viewable (e.g., to an operator, test engineer, etc.). Additionally, the example surface evaluator circuitry 102, implemented by the server 110, can access these measurements via the computer 108.

In this example, the surface evaluator circuitry 102 is implemented by the server 110. In some examples, the surface evaluator circuitry 102 is implemented by any other device (e.g., the computer 108) communicatively or directly coupled to the measurement device 106. The example surface evaluator circuitry 102 includes example model accessor circuitry 112, example region determination circuitry 114, example selection circuitry 116, example coordinates measurement circuitry 118, example reference determination circuitry 120, example comparison circuitry 122, and example smoothness determination circuitry 124. The example region determination circuitry 114 includes example association circuitry 126 and example boundary determination circuitry 128. The surface evaluator circuitry 102 of FIG. 1 may be instantiated (e.g., creating an instance of, bring into being for any length of time, materialize, implement, etc.) by programmable circuitry such as a Central Processor Unit (CPU) executing first instructions. Additionally or alternatively, the surface evaluator circuitry 102 of FIG. 1 may be instantiated (e.g., creating an instance of, bring into being for any length of time, materialize, implement, etc.) by (i) an Application Specific Integrated Circuit (ASIC) structured and/or configured in response to execution of second instructions to perform operations corresponding to the first instructions. It should be understood that some or all of the circuitry of FIG. 1 may, thus, be instantiated at the same or different times. Some or all of the circuitry of FIG. 1 may be instantiated, for example, in one or more threads executing concurrently on hardware and/or in series on hardware. Moreover, in some examples, some or all of the circuitry of FIG. 1 may be implemented by microprocessor circuitry executing instructions and/or performing operations to implement one or more virtual machines and/or containers.

The example model accessor circuitry 112 accesses the computer-generated model of the surface 104 of an object to be evaluated for smoothness. In some examples, the computer-generated model of the surface 104 may include and/or otherwise indicate any contours, grooves, curves, etc., of the surface 104. In some examples, the computer-generated model of the surface 104 may include and/or otherwise indicate any coatings, surface treatments, films, etc., deposited on the surface 104.

The example region determination circuitry 114 segments (e.g., divides, sections, etc.) the surface 104 (e.g., the computer-generated model of the surface 104) into a plurality of regions. The example region determination circuitry 114 segments the surface 104 such that each of the regions is adjacent to, in contact with, or overlapping at least another one of the regions. In some examples, the region determination circuitry 114 segments the surface 104 by determining a distribution (e.g., pattern, array, etc.) of locating points relative to the surface 104 based on at least one of an area of the surface 104, a contour of the surface 104, or a shape of the surface 104. In some examples, the locating points are coordinates, reference points, centroids, etc., that indicate positional information associated with the plurality of regions relative to the surface 104. The example region determination circuitry 114 includes the association circuitry 126 to associate the distribution of locating points to the surface 104 of the object. For example, the association circuitry 126 can overlay, project, etc., the locating points across the computer-generated model of the surface 104. Further, the example region determination circuitry 114 includes the boundary determination circuitry 128 to determine boundaries of the regions based on the locating points. The example boundary determination circuitry 128 can generate boundaries that surround (e.g., encircle) each of the locating points. In some examples, the boundary determination circuitry 128 determines boundaries that extend away from (e.g., spread out away from) the locating points to contact at least one other boundary. In some examples, each of the regions has a curved boundary. For example, the curved boundary of any region may form a circular or ovular perimeter. In other examples, the boundary of any region may form any enclosed geometric shape (e.g., square, rectangular, trapezoidal, etc.).

The example selection circuitry 116 selects one of the regions to be evaluated for smoothness. As used herein, the term “selected region” refers to such a region to be evaluated for smoothness. In some examples, the term “selected region” refers to the first region selected (e.g., randomly selected) by the selection circuitry 116 to be evaluated for smoothness. In other examples, the term “selected region” can refer to any of the regions selected (e.g., randomly selected) by the selection circuitry 116 to be evaluated for smoothness (subsequent to the first selected region).

The example coordinates measurement circuitry 118 measures a plurality of coordinates on the surface 104 corresponding to respective locations within the selected region. The example selected region includes an infinite number of locations (e.g., positional data points) within the boundary of the selected region. However, the example coordinates measurement circuitry 118 measures coordinates on the surface 104 for a predetermined/specified number (e.g., 500, 600, 1000, etc.) of respective locations within the selected region. Thus, for the selected region, the coordinates measurement circuitry 118 can accumulate a data set that includes a plurality of coordinates on the surface 104 corresponding to respective locations within that selected region. In some examples, the coordinates measurement circuitry 118 can trigger the measurement device 106 to scan the surface 104 to provide the coordinates measurements.

The example reference determination circuitry 120 determines a reference surface based on the measured coordinates. The example reference surface is a mathematical result/calculation that can represent the selected region of the surface 104. In some examples, the reference determination circuitry 120 determines the reference surface by calculating a best-fit surface. In some examples, the reference determination circuitry 120 determines the reference surface based on a nominal surface definition (e.g., a desired manufacturing specification associated with the surface 104). The example reference determination circuitry 120 determines reference surfaces for each of the regions in the plurality of regions. The plurality of regions are distributed across the surface 104 (e.g., at different locations), and the contour/shape of the surface 104 can vary. As a result, if the reference surface associated with the selected region is a first reference surface, then each of the other regions in the plurality of regions includes a reference surface different from the first reference surface. The example region determination circuitry 114 can determine the other reference surfaces by measuring coordinates on the surface 104 in each of the other regions across the contoured surface 104.

The example comparison circuitry 122 compares the measured coordinates to the reference surface associated with the selected region. In some examples, the comparison circuitry 122 compares the measured coordinates to the reference surface by determining a distance between the coordinates and corresponding coordinates on the reference surface. For example, the comparison circuitry 122 can access first measured coordinates on the surface 104, where the first measured coordinates are associated with a first location within the selected region. Additionally, the comparison circuitry 122 can access first corresponding coordinates on the reference surface, where the first corresponding coordinates are associated with the first location. In turn, the comparison circuitry 122 can determine a first distance between the first corresponding coordinates on the reference surface and the first measured coordinates on the surface 104. Similarly, the comparison circuitry 122 can determine these distances from the reference surface for any number of respective locations within the selected region. In other words, each set of the measured coordinates corresponds to respective distances (e.g., distinct distances) from the reference surface. Moreover, the comparison circuitry 122 can determine these distances from the reference surface within each of the regions in the plurality of regions.

The example smoothness determination circuitry 124 determines a smoothness parameter of the selected region based on the comparisons. For example, the smoothness determination circuitry 124 accesses each of the distances associated with the respective locations (e.g., all of the respective locations) within the selected region. As previously mentioned, each set of measured coordinates correspond to respective distances (e.g., distances from the reference surface). In turn, the smoothness determination circuitry 124 determines which set of the measured coordinates is a minimum value and which set of the measured coordinates is a maximum value. The example smoothness determination circuitry 124 determines which set of the measured coordinates is the minimum value based on the smallest value (e.g., valley) of the measured coordinates. For example, the smallest value of the measured coordinates may correspond to the shortest positive distance from the reference surface. In other words, if all of the sets of the measured coordinates are above the reference surface, then the smoothness determination circuitry 124 can determine the minimum value based on whichever set of the measured coordinates is the shortest distance from the reference surface.

Alternatively, the smallest value of the measured coordinates may correspond to the longest negative distance from the reference surface. In other words, if all of the sets of the measured coordinates are below the reference surface, then the smoothness determination circuitry 124 can determine the minimum value based on whichever set of the measured coordinates is the longest distance from the reference surface. In some examples, if some of the sets of the measured coordinates are above the reference surface and some of the sets of the measured coordinates (e.g., at least one set of the measured coordinates) are below the reference surface, then the smoothness determination circuitry 124 can determine the minimum value based on whichever set of the measured coordinates below the reference surface is the longest distance from the reference surface.

Similarly, the smoothness determination circuitry 124 determines which of the measured coordinates is the maximum value based on the largest value (e.g., peak) of the measured coordinates. For example, the largest value of the measured coordinates may correspond to the longest positive distance from the reference surface. In other words, if all of the sets of the measured coordinates are above the reference surface, then the smoothness determination circuitry 124 can determine the maximum value based on whichever set of the measured coordinates is the longest distance from the reference surface. Further, if some of the sets of the measured coordinates are above the reference surface (e.g., at least one set of the measured coordinates) and some of the sets of the measured coordinates are below the reference surface, then the smoothness determination circuitry 124 can determine the maximum value based on whichever set of the measured coordinates above the reference surface is the longest distance to the reference surface.

Alternatively, the largest value of the measured coordinates may be associated with the shortest negative distance from the reference surface. In other words, if all of the sets of the measured coordinates are below the reference surface, then the smoothness determination circuitry 124 can determine the maximum value based on whichever set of the measured coordinates is the shortest distance from the reference surface. In turn, the example smoothness determination circuitry 124 determines the smoothness parameter for the selected region based on the maximum value and the minimum value. For example, the smoothness determination circuitry 124 determines the smoothness parameter for the selected region by determining a difference (e.g., a peak to valley measurement) between the maximum value and the minimum value.

The example smoothness determination circuitry 124 compares the smoothness parameter to a threshold. If the example smoothness determination circuitry 124 determines that the smoothness parameter satisfies the threshold, then the smoothness determination circuitry 124 can determine that the selected region is substantially smooth. Alternatively, if the example smoothness determination circuitry 124 determines that the smoothness parameter exceeds (e.g., is greater than) the threshold, then the smoothness determination circuitry 124 can determine that the selected region is not substantially smooth. Similarly, the smoothness determination circuitry 124 can determine smoothness parameters for each of the other regions in the plurality of regions. As such, the smoothness determination circuitry 124 can evaluate the surface 104 based on the smoothness parameters associated with each of the other regions and the first selected region.

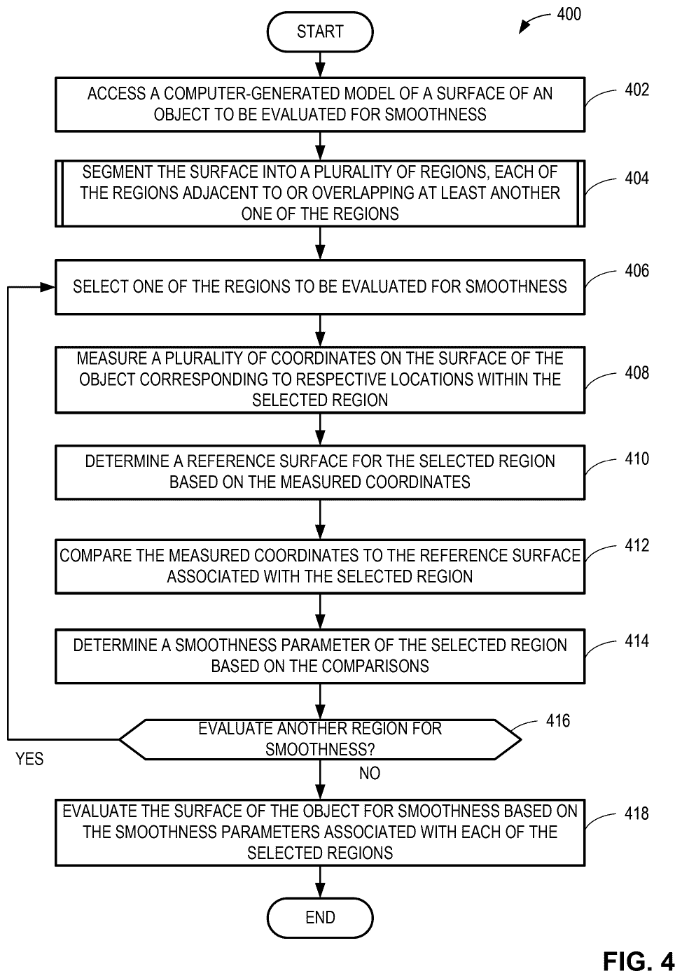

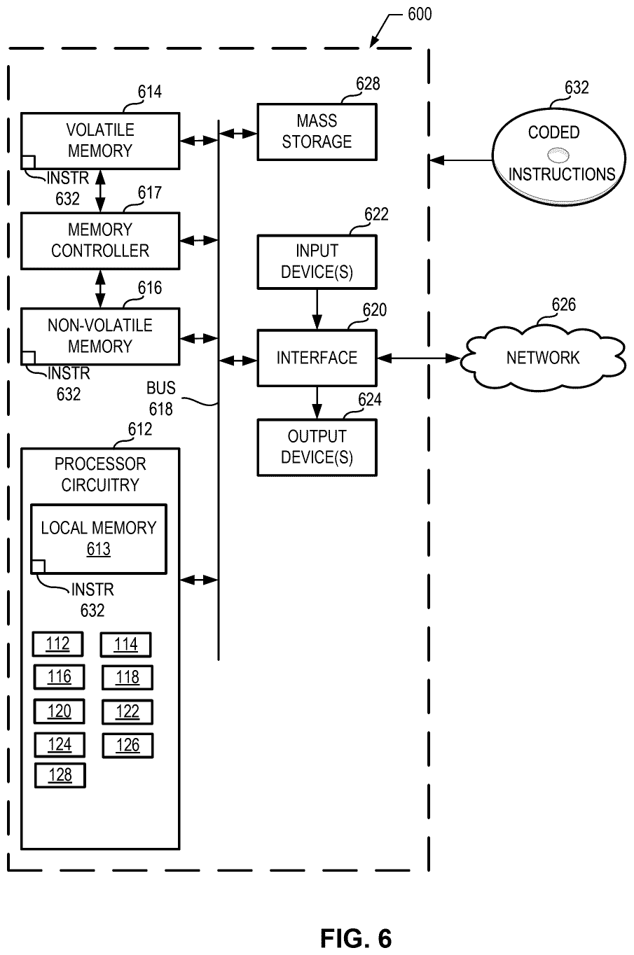

In some examples, the model accessor circuitry 112 is instantiated by programmable circuitry executing accessing instructions and/or configured to perform operations such as those represented by the flowchart of FIG. 4. In some examples, the surface evaluator circuitry 102 includes means for accessing. For example, the means for accessing may be implemented by the model accessor circuitry 112. In some examples, the model accessor circuitry 112 may be instantiated by programmable circuitry such as the example programmable circuitry 612 of FIG. 6 executing machine executable instructions such as those implemented by at least block 402 of FIG. 4. In some examples, the model accessor circuitry 112 may be instantiated by hardware logic circuitry, which may be implemented by an ASIC or XPU configured and/or structured to perform operations corresponding to the machine readable instructions. Additionally or alternatively, the model accessor circuitry 112 may be instantiated by any other combination of hardware, software, and/or firmware. For example, the model accessor circuitry 112 may be implemented by at least one or more hardware circuits (e.g., processor circuitry, discrete and/or integrated analog and/or digital circuitry, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

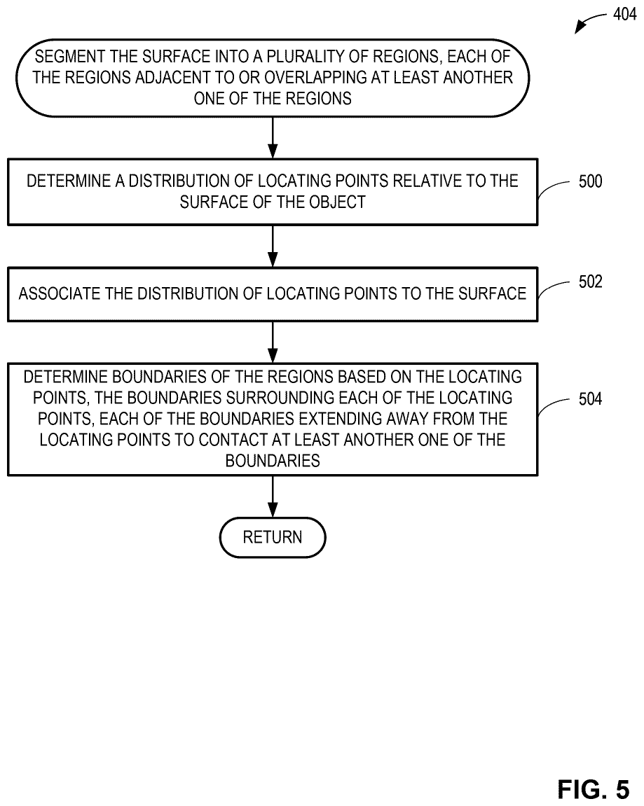

In some examples, the region determination circuitry 114 is instantiated by programmable circuitry executing region determining instructions and/or configured to perform operations such as those represented by the flowchart(s) of FIGS. 4 and 5. In some examples, the surface evaluator circuitry 102 includes first means for determining. For example, the first means for determining may be implemented by the region determination circuitry 114. In some examples, the region determination circuitry 114 may be instantiated by programmable circuitry such as the example programmable circuitry 612 of FIG. 6 executing machine executable instructions such as those implemented by at least block 404 of FIG. 4 and block 500 of FIG. 5. In some examples, the region determination circuitry 114 may be instantiated by hardware logic circuitry, which may be implemented by an ASIC or XPU configured and/or structured to perform operations corresponding to the machine readable instructions. Additionally or alternatively, the region determination circuitry 114 may be instantiated by any other combination of hardware, software, and/or firmware. For example, the region determination circuitry 114 may be implemented by at least one or more hardware circuits (e.g., processor circuitry, discrete and/or integrated analog and/or digital circuitry, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In some examples, the first means for determining includes means for associating. For example, the means for associating may be implemented by the association circuitry 126. In some examples, the association circuitry 126 may be instantiated by programmable circuitry such as the example programmable circuitry 612 of FIG. 6 executing machine executable instructions such as those implemented by at least block 502 of FIG. 5. In some examples, the association circuitry 126 may be instantiated by hardware logic circuitry, which may be implemented by an ASIC or XPU configured and/or structured to perform operations corresponding to the machine readable instructions. Additionally or alternatively, the association circuitry 126 may be instantiated by any other combination of hardware, software, and/or firmware. For example, the association circuitry 126 may be implemented by at least one or more hardware circuits (e.g., processor circuitry, discrete and/or integrated analog and/or digital circuitry, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate. In some examples, the association circuitry 126 is instantiated by programmable circuitry executing associating instructions and/or configured to perform operations such as those represented by the flowchart of FIG. 5.

In some examples, the first means for determining includes second means for determining. For example, the second means for determining may be implemented by the boundary determination circuitry 128. In some examples, the boundary determination circuitry 128 may be instantiated by programmable circuitry such as the example programmable circuitry 612 of FIG. 6 executing machine executable instructions such as those implemented by at least block 504 of FIG. 5. In some examples, the boundary determination circuitry 128 may be instantiated by hardware logic circuitry, which may be implemented by an ASIC or XPU configured and/or structured to perform operations corresponding to the machine readable instructions. Additionally or alternatively, the boundary determination circuitry 128 may be instantiated by any other combination of hardware, software, and/or firmware. For example, the boundary determination circuitry 128 may be implemented by at least one or more hardware circuits (e.g., processor circuitry, discrete and/or integrated analog and/or digital circuitry, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate. In some examples, the boundary determination circuitry 128 is instantiated by programmable circuitry executing boundary determination instructions and/or configured to perform operations such as those represented by the flowchart of FIG. 5.

In some examples, the selection circuitry 116 is instantiated by programmable circuitry executing selection instructions and/or configured to perform operations such as those represented by the flowchart of FIG. 4. In some examples, the surface evaluator circuitry 102 includes means for selecting. For example, the means for selecting may be implemented by the selection circuitry 116. In some examples, the selection circuitry 116 may be instantiated by programmable circuitry such as the example programmable circuitry 612 of FIG. 6 executing machine executable instructions such as those implemented by at least block 406 of FIG. 4. In some examples, the selection circuitry 116 may be instantiated by hardware logic circuitry, which may be implemented by an ASIC or XPU configured and/or structured to perform operations corresponding to the machine readable instructions. Additionally or alternatively, the selection circuitry 116 may be instantiated by any other combination of hardware, software, and/or firmware. For example, the selection circuitry 116 may be implemented by at least one or more hardware circuits (e.g., processor circuitry, discrete and/or integrated analog and/or digital circuitry, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In some examples, the coordinates measurement circuitry 118 is instantiated by programmable circuitry executing coordinates measurement instructions and/or configured to perform operations such as those represented by the flowchart of FIG. 4. In some examples, the surface evaluator circuitry 102 includes means for measuring. For example, the means for measuring may be implemented by the coordinates measurement circuitry 118. In some examples, the coordinates measurement circuitry 118 may be instantiated by programmable circuitry such as the example programmable circuitry 612 of FIG. 6 executing machine executable instructions such as those implemented by at least block 408 of FIG. 4. In some examples, coordinates measurement circuitry 118 may be instantiated by hardware logic circuitry, which may be implemented by an ASIC or XPU configured and/or structured to perform operations corresponding to the machine readable instructions. Additionally or alternatively, the coordinates measurement circuitry 118 may be instantiated by any other combination of hardware, software, and/or firmware. For example, the coordinates measurement circuitry 118 may be implemented by at least one or more hardware circuits (e.g., processor circuitry, discrete and/or integrated analog and/or digital circuitry, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In some examples, the reference determination circuitry 120 is instantiated by programmable circuitry executing reference determination instructions and/or configured to perform operations such as those represented by the flowchart of FIG. 4. In some examples, the surface evaluator circuitry 102 includes third means for determining. For example, the third means for determining may be implemented by the reference determination circuitry 120. In some examples, the reference determination circuitry 120 may be instantiated by programmable circuitry such as the example programmable circuitry 612 of FIG. 6 executing machine executable instructions such as those implemented by at least block 410 of FIG. 4. In some examples, the reference determination circuitry 120 may be instantiated by hardware logic circuitry, which may be implemented by an ASIC or XPU configured and/or structured to perform operations corresponding to the machine readable instructions. Additionally or alternatively, the reference determination circuitry 120 may be instantiated by any other combination of hardware, software, and/or firmware. For example, the reference determination circuitry 120 may be implemented by at least one or more hardware circuits (e.g., processor circuitry, discrete and/or integrated analog and/or digital circuitry, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In some examples, the comparison circuitry 122 is instantiated by programmable circuitry executing comparison instructions and/or configured to perform operations such as those represented by the flowchart of FIG. 4. In some examples, the surface evaluator circuitry 102 includes means for comparing. For example, the means for comparing may be implemented by the comparison circuitry 122. In some examples, the comparison circuitry 122 may be instantiated by programmable circuitry such as the example programmable circuitry 612 of FIG. 6 executing machine executable instructions such as those implemented by at least block 412 of FIG. 4. In some examples, the comparison circuitry 122 may be instantiated by hardware logic circuitry, which may be implemented by an ASIC or XPU configured and/or structured to perform operations corresponding to the machine readable instructions. Additionally or alternatively, the comparison circuitry 122 may be instantiated by any other combination of hardware, software, and/or firmware. For example, the comparison circuitry 122 may be implemented by at least one or more hardware circuits (e.g., processor circuitry, discrete and/or integrated analog and/or digital circuitry, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In some examples, the smoothness determination circuitry 124 is instantiated by programmable circuitry executing smoothness determination instructions and/or configured to perform operations such as those represented by the flowchart of FIG. 4. In some examples, the surface evaluator circuitry 102 includes fourth means for determining. For example, the fourth means for determining may be implemented by the smoothness determination circuitry 124. In some examples, the smoothness determination circuitry 124 may be instantiated by programmable circuitry such as the example programmable circuitry 612 of FIG. 6 executing machine executable instructions such as those implemented by at least blocks 414, 416, 418 of FIG. 4. In some examples, the smoothness determination circuitry 124 may be instantiated by hardware logic circuitry, which may be implemented by an ASIC or XPU configured and/or structured to perform operations corresponding to the machine readable instructions. Additionally or alternatively, the smoothness determination circuitry 124 may be instantiated by any other combination of hardware, software, and/or firmware. For example, the smoothness determination circuitry 124 may be implemented by at least one or more hardware circuits (e.g., processor circuitry, discrete and/or integrated analog and/or digital circuitry, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

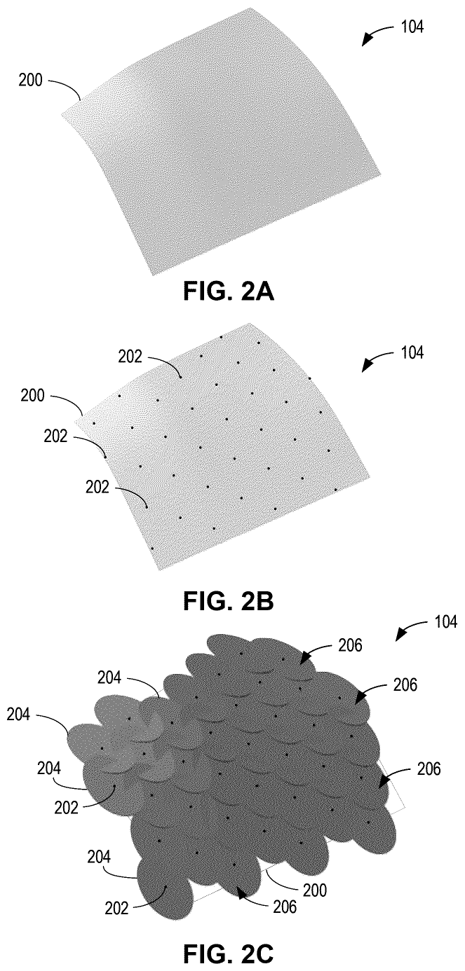

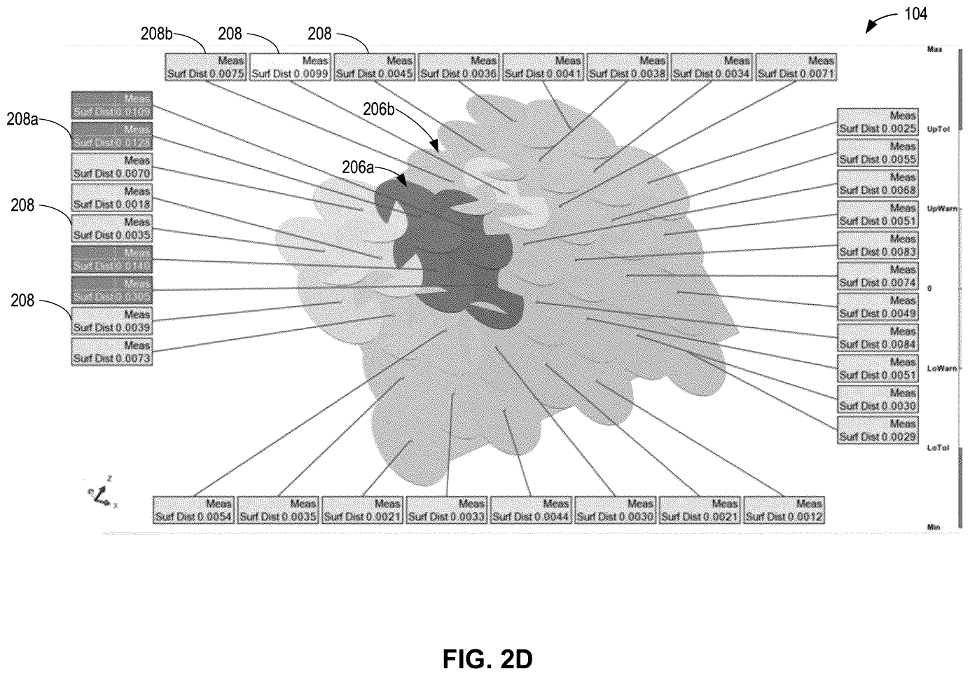

FIGS. 2A-2D illustrate various operations in an example process of implementing the example surface evaluator circuitry 102 of FIG. 1. Turning to FIG. 2A, an example computer-generated model 200 of the surface 104 is shown. The example surface evaluator circuitry 102 accesses the computer-generated model 200 to evaluate the surface 104 for smoothness.

In FIG. 2B, a distribution of example locating points 202 is shown. The example region determination circuitry 114 segments the computer-generated model 200 of the surface 104 by determining a distribution of the locating points 202 relative to the surface 104. In some examples, the locating points 202 are approximately evenly spaced across the surface 104. In some examples, the locating points 202 are randomly spaced across the surface 104. In the example of FIG. 2B, the region determination circuitry 114 distributes the locating points 202 in a grid-like pattern across the surface 104. Further, the example association circuitry 126 associates the distribution of the locating points 202 to the surface 104.

In FIG. 2C, example boundaries 204 of example regions 206 are shown. The example boundary determination circuitry 128 determines the boundaries 204 based on the locating points 202. In the example of FIG. 2C, the boundary determination circuitry 128 generates the boundaries 204 to surround each of the locating points 202. In particular, the boundaries 204 may be curved (e.g., ovular). Further, the boundaries 204 extend away from the locating points 202 to contact at least one other one of the boundaries 204.

In FIG. 2D, example smoothness parameters 208 are shown adjacent to the computer-generated model 200 of the surface 104. For example, the smoothness determination circuitry 124 determines that the smoothness parameter 208a associated with the region 206a is 0.0128 inches (in). Further, each of the regions 206 is shaded based on whether the smoothness parameters 208 are inside, outside, or approaching outside the threshold range. For example, the threshold range for the region 206a may be 0.010 in-0.012 in. The smoothness parameter 208a of 0.0128 in is greater than the maximum deviation of 0.012 in. Thus, the region 206a is shaded a first color (e.g., red) to indicate that the smoothness parameter 208a is outside of the threshold range. In some examples, the region 206a and/or the surface 104 may be flagged for additional inspection based on the shading. In some examples, the region determination circuitry 114 segments the region 206a into additional, smaller regions to further analyze the region 206a. In turn, the surface evaluator circuitry 102 can evaluate the additional regions within the region 206a in a similar manner.

In another example, the threshold range for the region 206b may be 0.0070 in-0.0080 in. The smoothness parameter 208b of 0.0075 in is less than the maximum deviation of 0.0080 in and greater than the minimum deviation of 0.0070 in. Thus, the region 206b is shaded a second color (e.g., green) different from the first color to indicate that the smoothness parameter 208b is within (e.g., satisfies) the threshold range. The example surface evaluator circuitry 102 can evaluate the surface 104 for smoothness by determining a number of the regions 206 that have a smoothness parameter that is outside of the respective threshold ranges for each of the regions 206.

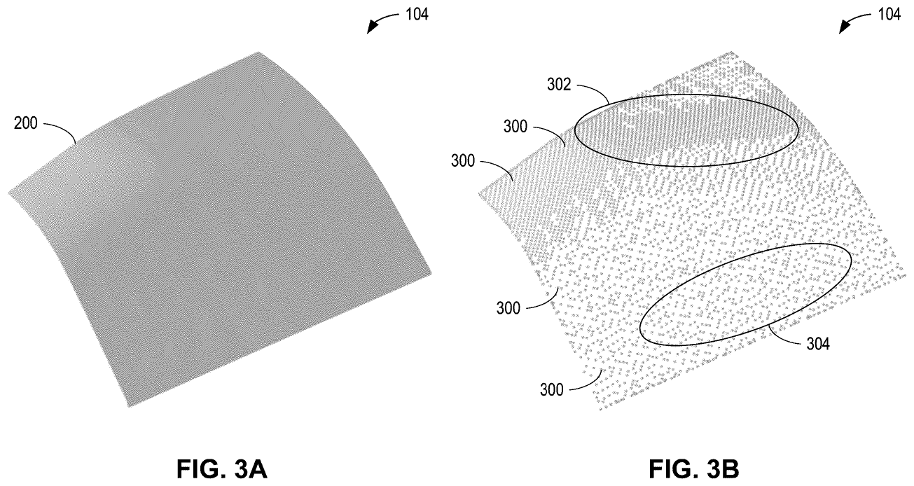

FIGS. 3A and 3B illustrate additional example operations of the example process of FIGS. 2A-2D. In FIG. 3A, the example computer-generated model 200 of the surface 104 is shown. In FIG. 3B, another distribution of example locating points 300 is shown. The example region determination circuitry 114 segments the computer-generated model 200 of the surface 104 by distributing the locating points 300 across the surface 104. In the example of FIG. 3B, the region determination circuitry 114 distributes the locating points 300 such that there is a higher concentration of the locating points 300 at positions on the surface 104 where there is more curvature/contouring. For example, example area 302 of the surface 104 may have more curvature/contouring than example area 304 of the surface 104. In some examples, the area 302 is a location of high criticality (e.g., high stress) associated with the surface 104. In any event, the region determination circuitry 114 may determine that certain areas (e.g., the area 302) of the surface 104 necessitate evaluation of smoothness at a higher resolution than other areas (e.g., the area 304). The example surface evaluator circuitry 102 can proceed to evaluate the surface 104 shown in FIG. 3B in a manner similar to the process described in connection with FIGS. 2A-2D.

While an example manner of implementing the surface evaluator circuitry 102 of FIG. 1 is illustrated in FIG. 1, one or more of the elements, processes, and/or devices illustrated in FIG. 1 may be combined, divided, re-arranged, omitted, eliminated, and/or implemented in any other way. Further, the example model accessor circuitry 112, the example region determination circuitry 114, the example association circuitry 126, the example boundary determination circuitry 128, the example selection circuitry 116, the example coordinates measurement circuitry 118, the example reference determination circuitry 120, the example comparison circuitry 122, the example smoothness determination circuitry 124, and/or, more generally, the example surface evaluator circuitry 102 of FIG. 1, may be implemented by hardware alone or by hardware in combination with software and/or firmware. Thus, for example, any of the example model accessor circuitry 112, the example region determination circuitry 114, the example association circuitry 126, the example boundary determination circuitry 128, the example selection circuitry 116, the example coordinates measurement circuitry 118, the example reference determination circuitry 120, the example comparison circuitry 122, the example smoothness determination circuitry 124, and/or, more generally, the example surface evaluator circuitry 102, could be implemented by programmable circuitry in combination with machine readable instructions (e.g., firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), and/or ASIC(s), programmable logic device(s) (PLD(s)). Further still, the example surface evaluator circuitry 102 of FIG. 1 may include one or more elements, processes, and/or devices in addition to, or instead of, those illustrated in FIG. 1, and/or may include more than one of any or all of the illustrated elements, processes and devices.

Flowchart(s) representative of example machine readable instructions, which may be executed by programmable circuitry to implement and/or instantiate the surface evaluator circuitry 102 of FIG. 1 and/or representative of example operations which may be performed by programmable circuitry to implement and/or instantiate the surface evaluator circuitry 102 of FIG. 1, are shown in FIGS. 4 and 5. The machine readable instructions may be one or more executable programs or portion(s) of one or more executable programs for execution by programmable circuitry such as the programmable circuitry 612 shown in the example programmable circuitry platform 600 discussed below in connection with FIG. 6 and/or may be one or more function(s) or portion(s) of functions to be performed by the example programmable circuitry. In some examples, the machine readable instructions cause an operation, a task, etc., to be carried out and/or performed in an automated manner in the real world. As used herein, “automated” means without human involvement.

The program may be embodied in instructions (e.g., software and/or firmware) stored on one or more non-transitory computer readable and/or machine readable storage medium such as cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), and/or any other storage device or storage disk. The instructions of the non-transitory computer readable and/or machine readable medium may program and/or be executed by programmable circuitry located in one or more hardware devices, but the entire program and/or parts thereof could alternatively be executed and/or instantiated by one or more hardware devices other than the programmable circuitry and/or embodied in dedicated hardware. The machine readable instructions may be distributed across multiple hardware devices and/or executed by two or more hardware devices (e.g., a server and a client hardware device). For example, the client hardware device may be implemented by an endpoint client hardware device (e.g., a hardware device associated with a human and/or machine user) or an intermediate client hardware device gateway (e.g., a radio access network (RAN)) that may facilitate communication between a server and an endpoint client hardware device. Similarly, the non-transitory computer readable storage medium may include one or more mediums. Further, although the example program is described with reference to the flowchart(s) illustrated in FIGS. 4 and 5, many other methods of implementing the example surface evaluator circuitry 102 may alternatively be used. For example, the order of execution of the blocks of the flowchart(s) may be changed, and/or some of the blocks described may be changed, eliminated, or combined. Additionally or alternatively, any or all of the blocks of the flow chart may be implemented by one or more hardware circuits (e.g., processor circuitry, discrete and/or integrated analog and/or digital circuitry, an ASIC, a comparator, an operational-amplifier (op-amp), a logic circuit, etc.) structured to perform the corresponding operation without executing software or firmware. The programmable circuitry may be distributed in different network locations and/or local to one or more hardware devices (e.g., a single-core processor (e.g., a single core CPU), a multi-core processor (e.g., a multi-core CPU, an XPU, etc.)). For example, the programmable circuitry may be a CPU located in the same package (e.g., the same integrated circuit (IC) package or in two or more separate housings), one or more processors in a single machine, multiple processors distributed across multiple servers of a server rack, multiple processors distributed across one or more server racks, etc., and/or any combination(s) thereof.

The machine readable instructions described herein may be stored in one or more of a compressed format, an encrypted format, a fragmented format, a compiled format, an executable format, a packaged format, etc. Machine readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, and/or produce machine executable instructions. For example, the machine readable instructions may be fragmented and stored on one or more storage devices, disks and/or computing devices (e.g., servers) located at the same or different locations of a network or collection of networks (e.g., in the cloud, in edge devices, etc.). The machine readable instructions may require one or more of installation, modification, adaptation, updating, combining, supplementing, configuring, decryption, decompression, unpacking, distribution, reassignment, compilation, etc., in order to make them directly readable, interpretable, and/or executable by a computing device and/or other machine. For example, the machine readable instructions may be stored in multiple parts, which are individually compressed, encrypted, and/or stored on separate computing devices, wherein the parts when decrypted, decompressed, and/or combined form a set of computer-executable and/or machine executable instructions that implement one or more functions and/or operations that may together form a program such as that described herein.

In another example, the machine readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine readable instructions may need to be configured (e.g., settings stored, data input, network addresses recorded, etc.) before the machine readable instructions and/or the corresponding program(s) can be executed in whole or in part. Thus, machine readable, computer readable and/or machine readable media, as used herein, may include instructions and/or program(s) regardless of the particular format or state of the machine readable instructions and/or program(s).

The machine readable instructions described herein can be represented by any past, present, or future instruction language, scripting language, programming language, etc. For example, the machine readable instructions may be represented using any of the following languages: C, C++, Java, C#, Perl, Python, JavaScript, HyperText Markup Language (HTML), Structured Query Language (SQL), Swift, etc.

As mentioned above, the example operations of FIGS. 4 and 5 may be implemented using executable instructions (e.g., computer readable and/or machine readable instructions) stored on one or more non-transitory computer readable and/or machine readable media. As used herein, the terms non-transitory computer readable medium, non-transitory computer readable storage medium, non-transitory machine readable medium, and/or non-transitory machine readable storage medium are expressly defined to include any type of computer readable storage device and/or storage disk and to exclude propagating signals and to exclude transmission media. Examples of such non-transitory computer readable medium, non-transitory computer readable storage medium, non-transitory machine readable medium, and/or non-transitory machine readable storage medium include optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms “non-transitory computer readable storage device” and “non-transitory machine readable storage device” are defined to include any physical (mechanical, magnetic and/or electrical) hardware to retain information for a time period, but to exclude propagating signals and to exclude transmission media. Examples of non-transitory computer readable storage devices and/or non-transitory machine readable storage devices include random access memory of any type, read only memory of any type, solid state memory, flash memory, optical discs, magnetic disks, disk drives, and/or redundant array of independent disks (RAID) systems. As used herein, the term “device” refers to physical structure such as mechanical and/or electrical equipment, hardware, and/or circuitry that may or may not be configured by computer readable instructions, machine readable instructions, etc., and/or manufactured to execute computer-readable instructions, machine-readable instructions, etc.

FIG. 4 is a flowchart representative of example machine readable instructions and/or example operations 400 that may be executed, instantiated, and/or performed by programmable circuitry to evaluate the surface 104 for smoothness. The example machine-readable instructions and/or the example operations 400 of FIG. 4 begin at block 402, at which the example model accessor circuitry 112 accesses the computer-generated model 200 of the surface 104 of an object to be evaluated for smoothness. In some examples, the computer-generated model 200 of the surface 104 may include and/or otherwise indicate any contours, grooves, curves, etc., of the surface 104. In some examples, the computer-generated model 200 of the surface 104 may include and/or otherwise indicate any coatings, surface treatments, films, etc., deposited on the surface 104.

At block 404, the example region determination circuitry 114 segments the surface 104 (e.g., the computer-generated model 200 of the surface) into a plurality of regions 206, each of the regions 206 adjacent to or overlapping at least another one of the regions 206, as described in detail below in connection with FIG. 5.

At block 406, the example selection circuitry 116 selects one of the regions 206 to be evaluated for smoothness. For example, the selection circuitry 116 selects the region 206a to be evaluated for smoothness.

At block 408, the example coordinates measurement circuitry 118 measures a plurality of coordinates on the surface 104 of the object corresponding to the respective locations within the selected region. For example, the coordinates measurement circuitry 118 measures coordinates on the surface 104 for a predetermined/specified number (e.g., 500, 600, 1000, etc.) of respective locations within the selected region 206a. Thus, for the region 206a, the coordinates measurement circuitry 118 can accumulate a data set that includes a plurality of coordinates on the surface 104 corresponding to respective locations within the region 206a.

At block 410, the example reference determination circuitry 120 determines a reference surface for the selected region based on the measured coordinates. In some examples, the reference determination circuitry 120 determines the reference surface by calculating a best-fit surface. In some examples, the reference determination circuitry 120 determines the reference surface based on a nominal surface definition.

At block 412, the example comparison circuitry 122 compares the measured coordinates to the reference surface associated with the selected region. In some examples, the comparison circuitry 122 compares the measured coordinates to the reference surface by determining a distance between the each of the coordinates and corresponding coordinates on the reference surface. In turn, the comparison circuitry 122 can subtract the each of the corresponding coordinates from the measured coordinates to determine the differences (e.g., deviations) between the surface 104 and the reference surface at respective locations in the region 206a.

At block 414, the example smoothness determination circuitry 124 determines a smoothness parameter of the selected region based on the comparisons. For example, the smoothness determination circuitry 124 accesses each of the distances associated with the respective locations within the selected region 206a. In turn, the smoothness determination circuitry 124 determines which of the measured coordinates is a minimum value and which of the measured coordinates is a maximum value. For example, the smoothness determination circuitry 124 determines the minimum value based on the smallest value of the measured coordinates. In some examples, the smallest value of the measured coordinates may be associated with the shortest positive distance from the reference surface or the longest negative distance from the reference surface. Further, the smoothness determination circuitry 124 determines the maximum value based on the largest value of the measured coordinates. In some examples, the largest value of the measured coordinates may be associated with the largest positive distance from the reference surface or the shortest negative distance from the reference surface. The example smoothness determination circuitry 124 determines a difference between the maximum value and the minimum value to determine the smoothness parameter (e.g., a peak to valley measurement) for the selected region. For example, the smoothness determination circuitry 124 determines that the smoothness parameter 208a associated with the region 206a is 0.0128 in based on a difference between a first one of the coordinates associated with a maximum distance from the reference surface and a second one of the coordinates associated with a minimum distance from the reference surface. Further, the smoothness determination circuitry 124 determines that the smoothness parameter 208a is outside of the threshold range 0.010 in-0.012 in.

At block 416, the example smoothness determination circuitry 124 determines whether to evaluate another one of the regions 206 for smoothness. For example, if the smoothness determination circuitry 124 determines to evaluate another one of the regions 206 for smoothness, then control of the process returns to block 406. In this manner, the example smoothness determination circuitry 124 can determine smoothness parameters for any number of (e.g., all) of the regions 206. Alternatively, if the smoothness determination circuitry 124 determines that there are no additional ones of the regions 206 to evaluate for smoothness, then control of the process proceeds to block 418.

At block 418, the example smoothness determination circuitry 124 evaluates the surface 104 of the object for smoothness based on the smoothness parameters (e.g., the smoothness parameters 208) associated with each of the selected regions 206. Then, the process ends.

FIG. 5 is a flowchart representative of example machine readable instructions and/or example operations that may be executed, instantiated, and/or performed by programmable circuitry to segment the surface 104 into a plurality of regions 206, each of the regions 206 adjacent to or overlapping at least another one of the regions 206. The example machine-readable instructions and/or the example operations 404 of FIG. 5 begin at block 500, at which the example region determination circuitry 114 determines a distribution of the locating points 202 relative to the surface 104 of the object. In some examples, the region determination circuitry 114 determines the distribution of the locating points 202 and/or the locating points 300 based on at least one of the area (e.g., the area 302, the area 304, etc.) of the surface 104, a contour of the surface 104, or a shape of the surface

At block 502, the example association circuitry 126 associates the distribution of the locating points 202 to the surface 104. For example, the association circuitry 126 can overlay, project, etc., the locating points 202 across the computer-generated model 200 of the surface 104.

At block 504, the example boundary determination circuitry 128 determines the boundaries 204 of the regions 206 based on the locating points 202, the boundaries 204 surrounding each of the locating points 202, each of the boundaries 204 extending away from the locating points 202 to contact at least another one of the boundaries 204. In some examples, each of the regions 206 has a curved boundary. For example, the curved boundary of any region may form a circular or ovular perimeter. Then, the process returns to FIG. 4.

FIG. 6 is a block diagram of an example programmable circuitry platform 600 structured to execute and/or instantiate the example machine-readable instructions and/or the example operations of FIGS. 4 and 5 to implement the surface evaluator circuitry 102 of FIG. 1. The programmable circuitry platform 600 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a DVD player, a CD player, a digital video recorder, a Blu-ray player, a gaming console, a personal video recorder, a set top box, a headset (e.g., an augmented reality (AR) headset, a virtual reality (VR) headset, etc.) or other wearable device, or any other type of computing and/or electronic device.

The programmable circuitry platform 600 of the illustrated example includes programmable circuitry 612. The programmable circuitry 612 of the illustrated example is hardware. For example, the programmable circuitry 612 can be implemented by one or more integrated circuits, logic circuits, microprocessors, CPUs, GPUs, DSPs, and/or microcontrollers from any desired family or manufacturer. The programmable circuitry 612 may be implemented by one or more semiconductor based (e.g., silicon based) devices. In this example, the programmable circuitry 612 implements the example model accessor circuitry 112, the example region determination circuitry 114, the example association circuitry 126, the example boundary determination circuitry 128, the example selection circuitry 116, the example coordinates measurement circuitry 118, the example reference determination circuitry 120, the comparison circuitry 122, and the example smoothness determination circuitry 124.

The programmable circuitry 612 of the illustrated example includes a local memory 613 (e.g., a cache, registers, etc.). The programmable circuitry 612 of the illustrated example is in communication with main memory 614, 616, which includes a volatile memory 614 and a non-volatile memory 616, by a bus 618. The volatile memory 614 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 616 may be implemented by flash memory and/or any other desired type of memory device. Access to the main memory 614, 616 of the illustrated example is controlled by a memory controller 617. In some examples, the memory controller 617 may be implemented by one or more integrated circuits, logic circuits, microcontrollers from any desired family or manufacturer, or any other type of circuitry to manage the flow of data going to and from the main memory 614, 616.

The programmable circuitry platform 600 of the illustrated example also includes interface circuitry 620. The interface circuitry 620 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface.

In the illustrated example, one or more input devices 622 are connected to the interface circuitry 620. The input device(s) 622 permit(s) a user (e.g., a human user, a machine user, etc.) to enter data and/or commands into the programmable circuitry 612. The input device(s) 622 can be implemented by, for example, an audio sensor, a microphone, a camera (still or video), a keyboard, a button, a mouse, a touchscreen, a trackpad, a trackball, an isopoint device, and/or a voice recognition system.

One or more output devices 624 are also connected to the interface circuitry 620 of the illustrated example. The output device(s) 624 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 620 of the illustrated example, thus, typically includes a graphics driver card, a graphics driver chip, and/or graphics processor circuitry such as a GPU.

The interface circuitry 620 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 626. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 600 of the illustrated example also includes one or more mass storage discs or devices 628 to store firmware, software, and/or data. Examples of such mass storage discs or devices 628 include magnetic storage devices (e.g., floppy disk, drives, HDDs, etc.), optical storage devices (e.g., Blu-ray disks, CDs, DVDs, etc.), RAID systems, and/or solid-state storage discs or devices such as flash memory devices and/or SSDs.

The machine readable instructions 632, which may be implemented by the machine readable instructions of FIGS. 4 and 5, may be stored in the mass storage device 628, in the volatile memory 614, in the non-volatile memory 616, and/or on at least one non-transitory computer readable storage medium such as a CD or DVD which may be removable.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that provide localized surface evaluation analyses for different regions of a curved/contoured surface. Thus, disclosed examples can indicate which regions, areas, portions, etc., of an example surface are smooth. To that end, disclosed examples can identify which regions of an example surface need to be redesigned, reevaluated, fixed, repaired, etc., instead of discarding the entire surface or the entire part. Disclosed examples can store and/or save results of these individual smoothness evaluations on a server, a workstation, etc. This allows examples disclosed herein to access historical data to better inform manufacturing decisions and design of other components/parts. Disclosed systems, apparatus, articles of manufacture, and methods improve the efficiency of using a computing device by providing mathematical computations to indicate the smoothness of each region of a curved/contoured surface. As such, examples disclosed herein reduce and/or eliminate subjective judgments of a human operator when evaluating a surface for smoothness. Disclosed systems, apparatus, articles of manufacture, and methods are accordingly directed to one or more improvement(s) in the operation of a machine such as a computer or other electronic and/or mechanical device.
Example 1 includes an apparatus comprising interface circuitry, machine-readable instructions, and at least one processor circuit to be programmed by the machine-readable instructions to access a computer-generated model of a three-dimensional (3D) surface of an object to be evaluated for smoothness, segment the 3D surface into a plurality of regions, each of the regions adjacent to or overlapping at least another one of the regions, select one of the regions to be evaluated for smoothness, measure a plurality of coordinates on the 3D surface of the object corresponding to respective locations within the selected region, determine a reference surface based on the measured coordinates, compare the coordinates to the reference surface, and determine a smoothness parameter of the selected region based on the comparisons.
Example 2 includes the apparatus of example 1, wherein the one or more of the at least one processor circuit is to determine the reference surface by calculating a best-fit surface.
Example 3 includes the apparatus of example 1, wherein the one or more at least one processor circuit is to compare the coordinates to the reference surface by determining a distance between the coordinates and corresponding coordinates on the reference surface.
Example 4 includes the apparatus of example 1, wherein each of the regions has a curved boundary.
Example 5 includes the apparatus of example 4, wherein the curved boundary forms a circular or ovular perimeter.
Example 6 includes the apparatus of example 1, wherein the reference surface is a first reference surface, wherein each of the other regions in the plurality of regions includes a reference surface different from the first reference surface, wherein the one or more of the at least one processor circuit is to determine the other reference surfaces by measuring coordinates on the 3D surface of the object in each of the other regions.
Example 7 includes the apparatus of example 6, wherein the selected region is a first region, wherein the one or more of the at least one processor is to determine smoothness parameters for the other regions by comparing, for each of the other regions, the measured coordinates on each of the other regions to corresponding coordinates on the respective reference surfaces, and evaluate the 3D surface of the object for smoothness based on the smoothness parameters associated with each of the other regions and the first region.
Example 8 includes the apparatus of example 1, wherein the one or more of the at least one processor circuit is to determine a distribution of the regions relative to the 3D surface of the object based on at least one of an area of the 3D surface of the object, a contour of the 3D surface of the object, or a shape of the 3D surface of the object.
Example 9 includes the apparatus of example 8, wherein the one or more of the at least one processor circuit is to segment the 3D surface into the plurality of regions by associating the distribution of locating points to the 3D surface of the object, and determining boundaries of the regions based on the locating points, the boundaries of the regions surrounding each of the locating points, each of the boundaries extending away from the locating points to contact at least one other boundary.
Example 10 includes At least one non-transitory machine-readable medium comprising machine-readable instructions to cause at least one processor circuit to at least access a computer-generated model of a three-dimensional (3D) surface of an object to be evaluated for smoothness, segment the 3D surface into a plurality of regions, each of the regions adjacent to or overlapping at least another one of the regions, select one of the regions to be evaluated for smoothness, measure a plurality of coordinates on the 3D surface of the object corresponding to respective locations within the selected region, determine a reference surface based on the measured coordinates, compare the coordinates to the reference surface, and determine a smoothness parameter of the selected region based on the comparisons.
Example 11 includes the at least one non-transitory machine-readable medium of example 10, wherein the machine-readable instructions are to cause one or more of the at least one processor circuit to determine the reference surface by calculating a best-fit surface.
Example 12 includes the at least one non-transitory machine-readable medium of example 10, wherein the machine-readable instructions are to cause one or more of the at least one processor circuit to compare the coordinates to the reference surface by determining a distance between the coordinates and corresponding coordinates on the reference surface.
Example 13 includes the at least one non-transitory machine-readable medium of example 10, wherein each of the regions has a curved boundary.
Example 14 includes the at least one non-transitory machine-readable medium of example 13, wherein the curved boundary forms a circular or ovular perimeter.
Example 15 includes the at least one non-transitory machine-readable medium of example 10, wherein the reference surface is a first reference surface, wherein each of the other regions in the plurality of regions includes a reference surface different from the first reference surface, wherein the machine-readable instructions are to cause one or more of the at least one processor circuit to determine the other reference surfaces by measuring coordinates on the 3D surface of the object in each of the other regions.
Example 16 includes the at least one non-transitory machine-readable medium of example 15, wherein the selected region is a first region, wherein the machine-readable instructions are to cause one or more of the at least one processor circuit to determine smoothness parameters for the other regions by comparing, for each of the other regions, the measured coordinates on each of the other regions to corresponding coordinates on the respective reference surfaces, and evaluate the 3D surface of the object for smoothness based on the smoothness parameters associated with each of the other regions and the first region.
Example 17 includes the at least one non-transitory machine-readable medium of example 10, wherein the machine-readable instructions are to cause one or more of the at least one processor circuit to determine a distribution of the regions relative to the 3D surface of the object based on at least one of an area of the 3D surface of the object, a contour of the 3D surface of the object, or a shape of the 3D surface of the object.
Example 18 includes the at least one non-transitory machine-readable medium of example 17, wherein the machine-readable instructions are to cause one or more of the at least one processor circuit to segment the 3D surface into the plurality of regions by associating the distribution of locating points to the 3D surface of the object, and determining boundaries of the regions based on the locating points, the boundaries of the regions surrounding each of the locating points, each of the boundaries extending away from the locating points to contact at least one other boundary.
Example 19 includes a method comprising accessing, by at least one processor circuit programmed by at least one instruction, a computer-generated model of a three-dimensional (3D) surface of an object to be evaluated for smoothness, segmenting, by one or more of the at least one processor circuit, the surface into a plurality of regions, each of the regions adjacent to or overlapping at least another one of the regions, selecting, by one or more of the at least one processor circuit, one of the regions to be evaluated for smoothness, measuring, by one or more of the at least one processor circuit, a plurality of coordinates on the 3D surface of the object corresponding to respective locations within the selected region, determining, by one or more of the at least one processor circuit, a reference surface based on the measured coordinates, comparing, by one or more of the at least one processor circuit, the coordinates on the reference surface, and determining, by one or more of the at least one processor circuit, a smoothness parameter of the selected region based on the comparisons.
Example 20 includes the method of example 19, wherein the one or more of the at least one processor circuit is to determine the reference surface by calculating a best-fit surface.
Example 21 includes the method of example 19, wherein the one or more of the at least one processor circuit is to compare the coordinates to the reference surface by determining a distance between the coordinates and corresponding coordinates on the reference surface.
Example 22 includes the method of example 19, wherein each of the regions has a curved boundary.
Example 23 includes the method of example 22, wherein the curved boundary forms a circular or ovular perimeter.
Example 24 includes the method of example 19, wherein the reference surface is a first reference surface, wherein each of the other regions in the plurality of regions includes a reference surface different from the first reference surface, wherein the one or more of the at least one processor circuit is to determine the other reference surfaces by measuring coordinates on the 3D surface of the object in each of the other regions.
Example 25 includes the method of example 24, wherein the selected region is a first region, further including determining smoothness parameters for the other regions by comparing, for each of the other regions, the measured coordinates on each of the other regions to corresponding coordinates on the respective reference surfaces, and evaluating the 3D surface of the object for smoothness based on the smoothness parameters associated with each of the other regions and the first region.
Example 26 includes the method of example 19, further including determining a distribution of the regions relative to the 3D surface of the object based on at least one of an area of the 3D surface of the object, a contour of the 3D surface of the object, or a shape of the 3D surface of the object.
Example 27 includes the method of example 26, wherein the one or more of the at least one processor circuit is to segment the 3D surface into the plurality of regions by associating the distribution of locating points to the 3D surface of the object, and determining boundaries of the regions based on the locating points, the boundaries of the regions surrounding each of the locating points, each of the boundaries extending away from the locating points to contact at least one other boundary.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

1. An apparatus comprising:
interface circuitry;
machine-readable instructions; and
at least one processor circuit to be programmed by the machine-readable instructions to:
access a computer-generated model of a three-dimensional (3D) surface of an object to be evaluated for smoothness;
segment the 3D surface into a plurality of regions, each of the regions adjacent to or overlapping at least another one of the regions;
select one of the regions to be evaluated for smoothness;
measure a plurality of coordinates on the 3D surface of the object corresponding to respective locations within the selected region;
determine a reference surface based on the measured coordinates;
compare the coordinates to the reference surface; and
determine a smoothness parameter of the selected region based on the comparisons.

2. The apparatus of claim 1, wherein the one or more of the at least one processor circuit is to determine the reference surface by calculating a best-fit surface.

3. The apparatus of claim 1, wherein the one or more at least one processor circuit is to compare the coordinates to the reference surface by determining a distance between the coordinates and corresponding coordinates on the reference surface.

4. The apparatus of claim 1, wherein each of the regions has a curved boundary.

5. The apparatus of claim 4, wherein the curved boundary forms a circular or ovular perimeter.

6. The apparatus of claim 1, wherein the reference surface is a first reference surface, wherein each of the other regions in the plurality of regions includes a reference surface different from the first reference surface, wherein the one or more of the at least one processor circuit is to determine the other reference surfaces by measuring coordinates on the 3D surface of the object in each of the other regions.

7. The apparatus of claim 6, wherein the selected region is a first region, wherein the one or more of the at least one processor is to:
determine smoothness parameters for the other regions by comparing, for each of the other regions, the measured coordinates on each of the other regions to corresponding coordinates on the respective reference surfaces; and
evaluate the 3D surface of the object for smoothness based on the smoothness parameters associated with each of the other regions and the first region.

8. The apparatus of claim 1, wherein the one or more of the at least one processor circuit is to determine a distribution of the regions relative to the 3D surface of the object based on at least one of an area of the 3D surface of the object, a contour of the 3D surface of the object, or a shape of the 3D surface of the object.

9. The apparatus of claim 8, wherein the one or more of the at least one processor circuit is to segment the 3D surface into the plurality of regions by:
associating the distribution of locating points to the 3D surface of the object; and
determining boundaries of the regions based on the locating points, the boundaries of the regions surrounding each of the locating points, each of the boundaries extending away from the locating points to contact at least one other boundary.

10. At least one non-transitory machine-readable medium comprising machine-readable instructions to cause at least one processor circuit to at least:
access a computer-generated model of a three-dimensional (3D) surface of an object to be evaluated for smoothness;
segment the 3D surface into a plurality of regions, each of the regions adjacent to or overlapping at least another one of the regions;
select one of the regions to be evaluated for smoothness;
measure a plurality of coordinates on the 3D surface of the object corresponding to respective locations within the selected region;
determine a reference surface based on the measured coordinates;
compare the coordinates to the reference surface; and
determine a smoothness parameter of the selected region based on the comparisons.

11. The at least one non-transitory machine-readable medium of claim 10, wherein the machine-readable instructions are to cause one or more of the at least one processor circuit to determine the reference surface by calculating a best-fit surface.

12. The at least one non-transitory machine-readable medium of claim 10, wherein the machine-readable instructions are to cause one or more of the at least one processor circuit to compare the coordinates to the reference surface by determining a distance between the coordinates and corresponding coordinates on the reference surface.

13. The at least one non-transitory machine-readable medium of claim 10, wherein each of the regions has a curved boundary.

14. The at least one non-transitory machine-readable medium of claim 13, wherein the curved boundary forms a circular or ovular perimeter.

15. The at least one non-transitory machine-readable medium of claim 10, wherein the reference surface is a first reference surface, wherein each of the other regions in the plurality of regions includes a reference surface different from the first reference surface, wherein the machine-readable instructions are to cause one or more of the at least one processor circuit to determine the other reference surfaces by measuring coordinates on the 3D surface of the object in each of the other regions.

16. The at least one non-transitory machine-readable medium of claim 15, wherein the selected region is a first region, wherein the machine-readable instructions are to cause one or more of the at least one processor circuit to:
determine smoothness parameters for the other regions by comparing, for each of the other regions, the measured coordinates on each of the other regions to corresponding coordinates on the respective reference surfaces; and
evaluate the 3D surface of the object for smoothness based on the smoothness parameters associated with each of the other regions and the first region.

17. The at least one non-transitory machine-readable medium of claim 10, wherein the machine-readable instructions are to cause one or more of the at least one processor circuit to determine a distribution of the regions relative to the 3D surface of the object based on at least one of an area of the 3D surface of the object, a contour of the 3D surface of the object, or a shape of the 3D surface of the object.

18. The at least one non-transitory machine-readable medium of claim 17, wherein the machine-readable instructions are to cause one or more of the at least one processor circuit to segment the 3D surface into the plurality of regions by:
associating the distribution of locating points to the 3D surface of the object; and
determining boundaries of the regions based on the locating points, the boundaries of the regions surrounding each of the locating points, each of the boundaries extending away from the locating points to contact at least one other boundary.

19. A method comprising:
accessing, by at least one processor circuit programmed by at least one instruction, a computer-generated model of a three-dimensional (3D) surface of an object to be evaluated for smoothness;
segmenting, by one or more of the at least one processor circuit, the surface into a plurality of regions, each of the regions adjacent to or overlapping at least another one of the regions;
selecting, by one or more of the at least one processor circuit, one of the regions to be evaluated for smoothness;
measuring, by one or more of the at least one processor circuit, a plurality of coordinates on the 3D surface of the object corresponding to respective locations within the selected region;
determining, by one or more of the at least one processor circuit, a reference surface based on the measured coordinates;
comparing, by one or more of the at least one processor circuit, the coordinates on the reference surface; and
determining, by one or more of the at least one processor circuit, a smoothness parameter of the selected region based on the comparisons.

20. (canceled)

21. The method of claim 19, wherein the one or more of the at least one processor circuit is to compare the coordinates to the reference surface by determining a distance between the coordinates and corresponding coordinates on the reference surface.

22.-27. (canceled)
